(19) United States
(12) Patent Application Publication
(10) Pub. No.: US 2023/0375932 A1
(43) Pub. Date: Nov. 23, 2023

(54) RESIST COMPOUND AND UNDERLAYER COMPOUND FOR PHOTOLITHOGRAPHY, MULTILAYERED STRUCTURE FORMED USING THE SAME, AND METHOD FOR MANUFACTURING SEMICONDUCTOR DEVICES USING THE SAME

(71) Applicant: Inha University Research and Business Foundation, Incheon (KR)

(72) Inventors: Jinkyun LEE, Incheon (KR); Yejin KU, Incheon (KR); Hyungju AHN, Bucheon-si (KR)

(73) Assignee: Inha University Research and Business Foundation, Incheon (KR)

(21) Appl. No.: 18/307,461

(22) Filed: Apr. 26, 2023

(30) Foreign Application Priority Data
May 17, 2022 (KR) 10-2022-0060058
Dec. 27, 2022 (KR) 10-2022-0186178

(51) Int. Cl. G03F 7/11; G03F 7/004; H01L 21/027; H01L 21/311; H01L 21/308; G03F 7/20; G03F 7/32

(52) U.S. Cl. CPC G03F 7/11; G03F 7/0043; H01L 21/0274; H01L 21/31144; H01L 21/3081; H01L 21/3085; H01L 21/3086; H01L 21/3088; G03F 7/2004; G03F 7/32; H01L 21/32139

(57) ABSTRACT

Provided are a resist compound and an underlayer compound, which may improve the resolution and sensitivity of a resist pattern and restrain the collapse of the resist pattern. The underlayer compound includes a cellulose structure having at least one hydroxyl group (—OH) and at least one vinyl silyl group. The resist compound includes an alkylated metal oxide nanocluster having a counter anion.

### CROSS-REFERENCE TO RELATED APPLICATIONS

This U.S. non-provisional patent application claims priority under 35 U.S.C. § 119 of Korean Patent Application Nos. 10-2022-0060058, filed on May 17, 2022, and 10-2022-0186178, filed on Dec. 27, 2022, the entire contents of which are hereby incorporated by reference.

### BACKGROUND

The present disclosure herein relates to a resist compound and a underlayer compound for photolithography, a multilayered structure formed using the same, and a method for manufacturing a semiconductor device using the same.

Photolithography may include an exposing process and a developing process. The conductance of the exposing process may include exposing a resist layer to a specific wavelength of light to induce the change of the chemical structure of the resist layer. The conductance of the developing process may include the selective removing of the exposed part or the unexposed part of the resist layer by using a solubility difference between the exposed part and the unexposed part.

Recently, as semiconductor devices are highly integrated and downsized, the line width of patterns in semiconductor devices are miniaturized. In order to form minute patterns, various studies are conducted to improve the resolution and sensitivity of resist patterns formed by photolithography and to restrain the collapse of resist patterns.

### SUMMARY

The task for solving of the present disclosure is to provide a resist compound and an underlayer compound, which may improve the resolution and sensitivity of resist patterns and restrain the collapse of resist patterns, a multilayered structure formed using the same, and a method for manufacturing a semiconductor device using the same.

The task for solving of the present disclosure is not limited to the aforementioned tasks, and unreferred other tasks may be clearly understood by a person skilled in the art from the description below.

According to an embodiment of the inventive concept, an underlayer compound for photolithography may include a structure of Formula 1.

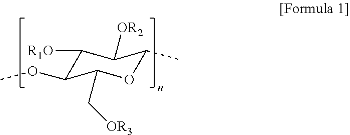

In Formula 1, R₁, R₂ and R₃ are each independently hydrogen, deuterium, or a functional group represented by Formula 2, Formula 3 or Formula 4, and “n” is an integer of 2 to 10,000.

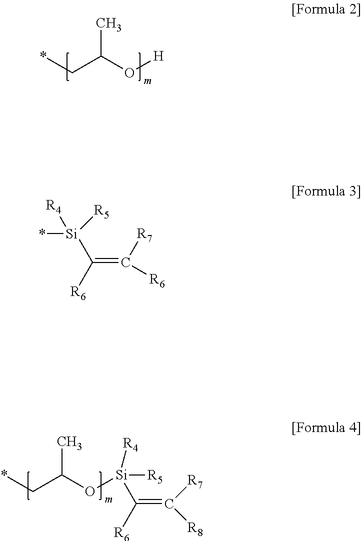

In Formula 2 and Formula 4, “m” is an integer of 1 to 20.

In Formula 3 and Formula 4, R₄, R₅, R₆, R₇ and R₈ are each independently hydrogen, deuterium, or an alkyl group of 1 to 3 carbon atoms.

In Formula 2 to Formula 4, * is a part combined with oxygen in Formula 1.

A resist compound for photolithography according to the inventive concept may include an alkylated metal oxide nanocluster having a counter anion. The alkylated metal oxide nanocluster may include a core structure including a metal oxide and an alkyl group of 1 to 20 carbon atoms, bonded to a metal element of the core structure. The counter anion may be an alkyl carboxylic acid anion of 2 to 20 carbon atoms, an alkyl ether alkyl carboxylic acid anion of 3 to 20 carbon atoms, an alkyl ether alkyl ether alkyl carboxylic acid anion of 4 to 20 carbon atoms, a fluoroalkyl carboxylic acid anion of 2 to 20 carbon atoms, a fluoroalkyl ether fluoroalkyl carboxylic acid anion of 3 to 20 carbon atoms or a fluoroalkyl ether fluoroalkyl ether fluoroalkyl carboxylic acid anion of 4 to 20 carbon atoms.

A multilayered structure according to the inventive concept may include a lower layer, an underlayer on the lower layer, and a photoresist layer on the underlayer. The underlayer may include a cellulose structure having at least one hydroxyl group (—OH) and at least one vinyl silyl group. The photoresist layer may include an alkylated metal oxide nanocluster having a counter anion. The alkylated metal oxide nanocluster may include a core structure including a metal oxide and an alkyl group of 1 to 20 carbon atoms, bonded to a metal element of the core structure.

A method for manufacturing a semiconductor device according to the inventive concept may include forming an underlayer on a lower layer, and forming a photoresist layer on the under layer. The forming of the photoresist layer may include applying a resist compound using a hydrophobic or aromatic solvent on the underlayer. The underlayer may include an underlayer compound having hydrophilicity. The underlayer compound may include a cellulose structure having at least one hydroxyl group (—OH) and at least one vinyl silyl group.

### BRIEF DESCRIPTION OF THE FIGURES

The accompanying drawings are included to provide a further understanding of the inventive concept, and are incorporated in and constitute a part of this specification. The drawings illustrate example embodiments of the inventive concept and, together with the description, serve to explain principles of the inventive concept. In the drawings:

FIG. 1 is a graph showing the nuclear magnetic resonance spectrum results of an underlayer compound produced according to Synthetic Example 1;

FIG. 2 is a graph showing the Fourier transform infrared (FT-IR) spectrum of an underlayer thin film formed according to Synthetic Example 2;

FIG. 3 and FIG. 4 are graphs showing the evaluation results of the solubility of underlayer compounds according to Experimental Example 1 and Experimental Example 2;

FIG. 5 to FIG. 8 are cross-sectional views showing a method for manufacturing a semiconductor device according to embodiments of the inventive concept;

FIG. 9 shows atomic force microscopic images showing measurement results on the surface roughness of an underlayer and a photoresist thin film formed according to Experimental Example 3;

FIG. 10 is a graph showing the evaluation results on the change of the solubility of a photoresist thin film according to Experimental Example 4;

FIG. 11 shows scanning electron microscopic images of a photoresist pattern formed according to Experimental Example 5; and

FIG. 12 is a graph showing the evaluation results on the solubility change of a photoresist thin film according to Experimental Example 6.

### DETAILED DESCRIPTION

Preferred embodiments of the inventive concept will be explained with reference to the accompany drawings for sufficient understanding of the configurations and effects of the inventive concept. The inventive concept may, however, be embodied in various forms, have various modifications and should not be construed as limited to the embodiments set forth herein. The embodiments are provided to complete the disclosure of the inventive concept through the explanation of the embodiments and to completely inform a person having ordinary knowledge in this technical field to which the inventive concept belongs of the scope of the inventive concept.

The terminology used herein is for the purpose of describing example embodiments only and is not intended to be limiting of the inventive concept. In the disclosure, the singular forms are intended to include the plural forms as well, unless the context clearly indicates otherwise. It will be further understood that the terms “comprises” and/or “comprising,” when used in this specification, specify the presence of stated elements, but do not preclude the presence or addition of one or more other elements.

In the present description, an alkyl group includes a monovalent saturated hydrocarbon group of a linear chain, branched chain or cyclic chain, unless otherwise indicated.

In the description, a case of not drawing a chemical bond at a position where a chemical bond is required, may mean that a hydrogen atom is bonded, unless otherwise defined.

Hereinafter, embodiments of the inventive concept will be explained in detail with reference to attached drawings. The same reference numerals are used for the same constituent elements on the drawings, and repeated explanation thereon will be omitted.

An underlayer compound according to embodiments of the inventive concept will be explained.

The underlayer compound according to embodiments of the inventive concept may be used for the manufacture of a semiconductor device and may be used in a photolithography process for the manufacture of a semiconductor device. The underlayer compound may be used, for example, in an extreme ultraviolet or e-beam lithography process. The extreme ultraviolet may mean ultraviolet having a wavelength of about 10 nm to about 124 nm, in detail, a wavelength of about 13.0 nm to about 13.9 nm, in more detail, a wavelength of about 13.4 nm to about 13.6 nm.

The underlayer compound may include a cellulose structure having at least one hydroxyl group (—OH) and at least one vinyl silyl group. The underlayer compound may include a structure of Formula 1.

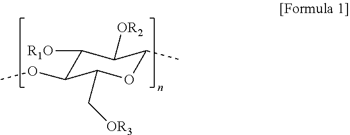

In Formula 1, R₁, R₂ and R₃ are each independently hydrogen, deuterium, or a functional group represented by Formula 2, Formula 3 or Formula 4.

In Formula 1, “n” is an integer of 2 to 10,000.

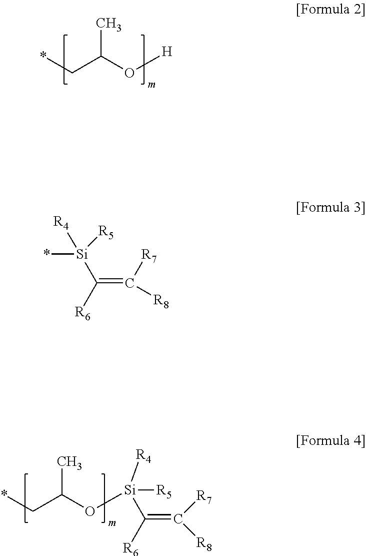

In Formula 2 and Formula 4, “m” is an integer of 1 to 20.

In Formula 3 and Formula 4, R₄, R₅, R₆, R₇ and R₈ are each independently hydrogen, deuterium or an alkyl group of 1 to 3 carbon atoms.

In Formula 3 and Formula 4, * is a part combined with oxygen in Formula 1.

Each of Formula 3 and Formula 4 may include a vinyl silyl group and derivatives thereof. For example, Formula 3 may include a functional group represented by Formula 3-1, and Formula 4 may include a functional group represented by Formula 4-1.

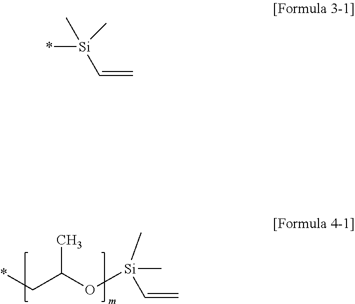

In Formula 3-1 and Formula 4-1, * is a part combined with oxygen in Formula 1, and “m” is an integer of 1 to 20.

In Formula 1, at least one among R₁, R₂ and R₃ may be a functional group represented by Formula 3 or Formula 4. Accordingly, the underlayer compound may include a vinyl silyl group and derivatives thereof. The vinyl silyl group of the underlayer compound may make a chemical bond with radicals produced from a resist compound which will be explained later.

In Formula 1, another one among R₁, R₂ and R₃ may be hydrogen, deuterium or a functional group represented by Formula 2. Accordingly, the underlayer compound may include a hydroxyl group (—OH) and may have hydrophilicity.

According to some embodiments, the underlayer compound may include a crosslinked structure of materials represented by Formula 1, crosslinked by using tetramethoxymethyl glycoluril (TMMGU) as a curing agent. In an embodiment, the underlayer compound may include a structure of Formula 5. Formula 5 may be a crosslinked structure of the materials represented by Formula 1, crosslinked by using tetramethoxymethyl glycoluril (TMMGU) as a curing agent. Formula 5 may be a structure formed by reacting the hydroxyl group (—OH) of Formula 1 with the —CH₃ group of TMMGU.

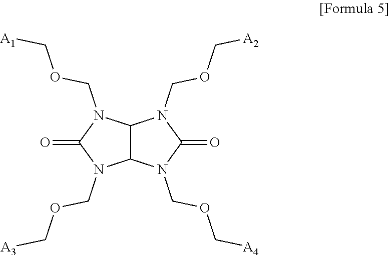

In Formula 5, A₁, A₂, A₃ and A₄ may each independently include a cellulose structure having at least one hydroxyl group (—OH) and at least one vinyl silyl group.

In Formula 5, A₁, A₂, A₃ and A₄ may be each independently represented by Formula 6, Formula 7, Formula 8, Formula 9, Formula 10 or Formula 11.

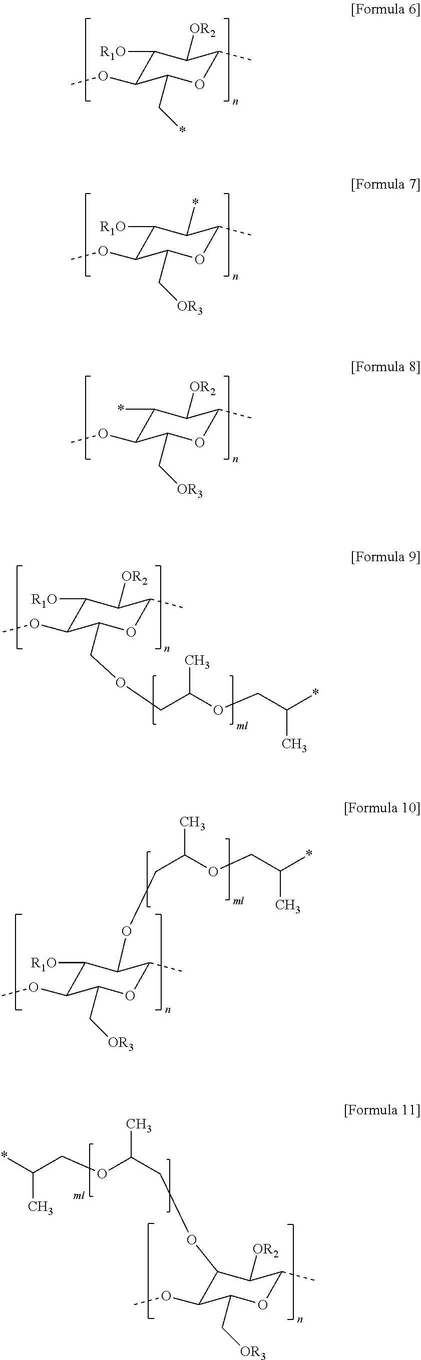

In Formula 6 to Formula 11, R₁, R₂ and R₃ are each independently hydrogen, deuterium or a functional group represented by Formula 2, Formula 3 or Formula 4. “n” is an integer of 2 to 10,000, and “m1” is an integer of 1 to 19. A case where “m1” is 0, means that a single bond is formed between oxygen and carbon. In Formula 6 to Formula 11, * is a part combined with carbon in Formula 5.

In Formula 6 to Formula 11, at least one among R₁, R₂ and R₃ may be a functional group represented by Formula 3 or Formula 4. Accordingly, the underlayer compound may include a vinyl silyl group and derivatives thereof. The vinyl silyl group of the underlayer compound may form a chemical bond with a radical produced from a resist compound which will be explained later. In Formula 6 to Formula 11, another one among R₁, R₂ and R₃ may be hydrogen, deuterium or a functional group represented by Formula 2. Accordingly, the underlayer compound may include a hydroxyl group (—OH) and may have hydrophilicity.

The synthesis of the underlayer compound of Formula 1 may be carried out according to Reaction 1.

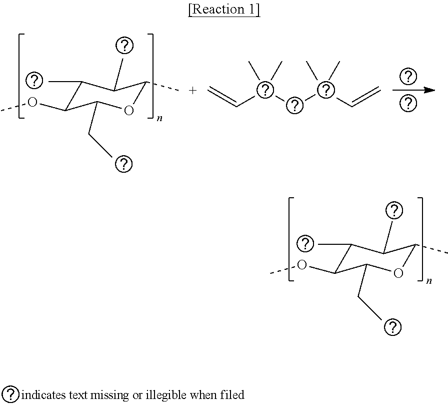

In Reaction 1, R₉, R₁₀ and R₁₁ of a starting material may be hydrogen, deuterium or a functional group represented by Formula 2. At least one hydroxyl group (—OH) of the starting material may be substituted with a vinyl silyl group, and accordingly, the underlayer compound of Formula 1 may be produced. In Reaction 1, “n” is an integer of 2 to 10,000.

### [Synthesis Example 1] Synthesis of Underlayer Compound of Formula 1 (Reaction 1)

To a 100 cm³ seal tube, hydroxypropyl cellulose (HPC, 1 g), saccharin (2.2 mg) and 1,4-dioxane (20 cm³) were injected. After that, a solution obtained by dissolving HPC at about 100° C., was cooled to room temperature. The seal tube was opened, and 1,3-divinyltetramethyldisilazane (DVS, 0.44 g) was injected, followed by reacting at about 120° C. for about 12 hours. The reaction solution thus obtained was cooled to room temperature. Tetrahydrofuran (THF, 20 cm³) was injected to the reaction solution for dilution, and the diluted reaction solution was dropwisely added to hexane to form a precipitate. The resultant thus obtained was filtered and dried to obtain a final product (a pale brown material having very high viscosity) which was the underlayer compound (DVS-HPC) of Formula 1.

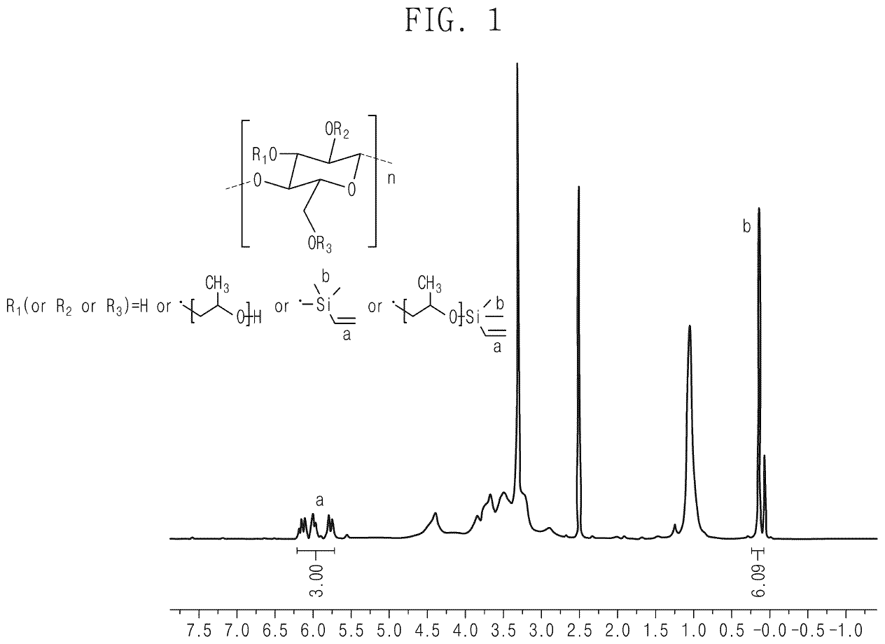

FIG. 1 is a graph showing the nuclear magnetic resonance spectrum results of the underlayer compound produced according to Synthetic Example 1. Referring to FIG. 1, it could be confirmed that the underlayer compound produced according to Synthetic Example 1 includes a vinyl silyl group.

### [Synthesis Example 2] Synthesis of Underlayer Compound of Formula 5

The underlayer compound (DVS-HPC, 50 mg) of Formula 1, produced according to Synthetic Example 1, 1,3,4,6-tetrakis(methoxymethyl)glycoluril (20 mg), and pyridinium p-toluenesulfonate (6 mg) were dissolved in propylene glycol mono-methyl ether (PGME, 1 cm³) to prepare a solution. The solution was applied by spin coating on a surface-untreated silicon substrate (bare Si substrate) at about 1500 rpm for about 60 seconds to form a underlayer thin film (a thickness of about 700 nm). The underlayer thin film was heated at about 130° C. for about 3 minutes to form a crosslinked underlayer thin film (a thickness of about 600 nm) including the underlayer compound of Formula 5. The underlayer thin film and the crosslinked underlayer thin film were measured by an attenuated total reflection (ATR) method using an infrared spectrometer (Bruker VERTEX 80V).

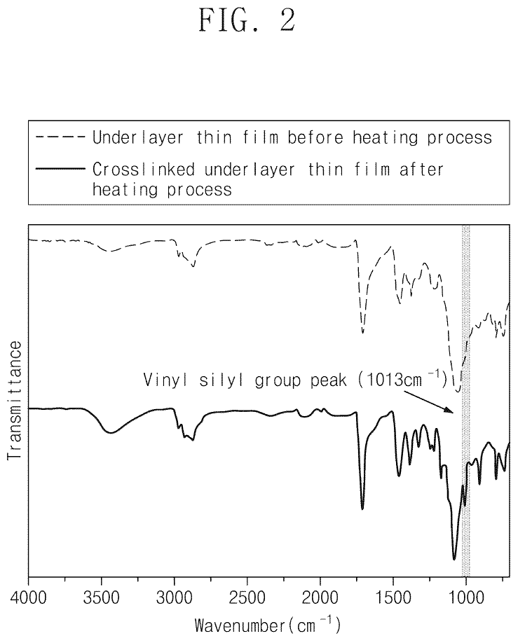

FIG. 2 is a graph showing the Fourier transform infrared (FT-IR) spectrum of the underlayer thin film formed by Synthetic Example 2. Referring to FIG. 2, the presence of the specific peak of a vinyl silyl group was confirmed in both the underlayer thin film before a heating process and the crosslinked underlayer thin film after the heating process.

### [Experimental Example 1] Evaluation of Solubility of Underlayer Compound of Formula 1

A solution (about 1.3 wt/vol %) obtained by dissolving the underlayer compound (DVC-HPC) of Formula 1 obtained according to Synthetic Example 1 in propylene glycol mono-methyl ether (PGME) was applied by spin coating on a surface-untreated silicon substrate (bare Si substrate) at about 3000 rpm for about 60 seconds, and heated at about 80° C. for about 1 minute. Accordingly, an underlayer thin film (a thickness of about 65 nm) was formed. The substrate on which the underlayer thin film was formed was immersed in PGME, propylene glycol mono-methyl ether acetate (PGMEA), 2-heptanone, toluene, benzotrifluoride, methyl iso-butyl ketone (MIBK), methanol and water for 1 minute each and dried. After that, the thickness of the underlayer thin film remained on the substrate was measured using an Alpha-Step® D-300 stylus profiler of Kla-Tencor Co.

### [Experimental Example 2] Evaluation of Solubility of Underlayer Compound of Formula 5

A solution was prepared by dissolving the underlayer compound (DVS-HPC, 20 mg) of Formula 1 produced according to Synthetic Example 1, 1,3,4,6-tetrakis(methoxymethyl)glycoluril (8 mg), and pyridinium p-toluenesulfonate (2.4 mg) in propylene glycol mono-methyl ether (PGME, 1 cm³). The solution was applied by spin coating on a surface-untreated silicon substrate (bare Si substrate) at about 3000 rpm for about 60 seconds, followed by heating at about 130° C. for about 3 minutes. Accordingly, a crosslinked underlayer thin film (a thickness of about 150 nm) including the underlayer compound of Formula 5 was formed. The substrate on which the crosslinked underlayer thin film was formed was immersed in PGME, propylene glycol mono-methyl ether acetate (PGMEA), 2-heptanone, toluene, benzotrifluoride, methyl iso-butyl ketone (MIBK), cyclohexanone, methanol, IPA and water for 1 minute each and dried. After that, the thickness of the crosslinked underlayer thin film remained on the substrate was measured using an Alpha-Step® D-300 stylus profiler of Kla-Tencor C.

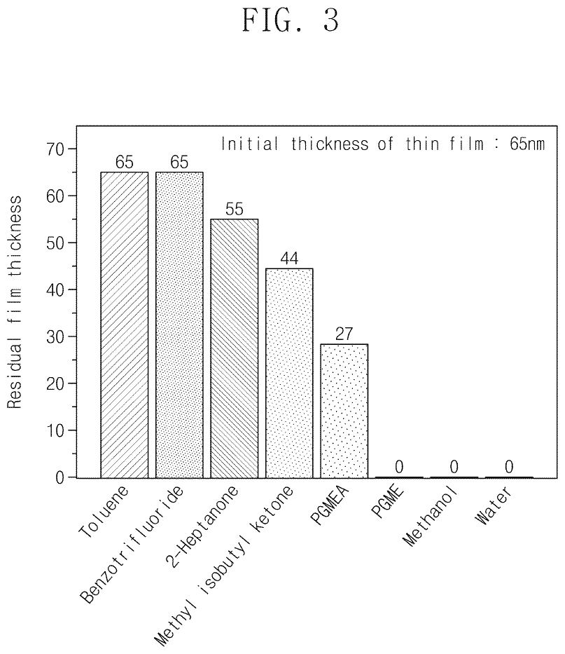

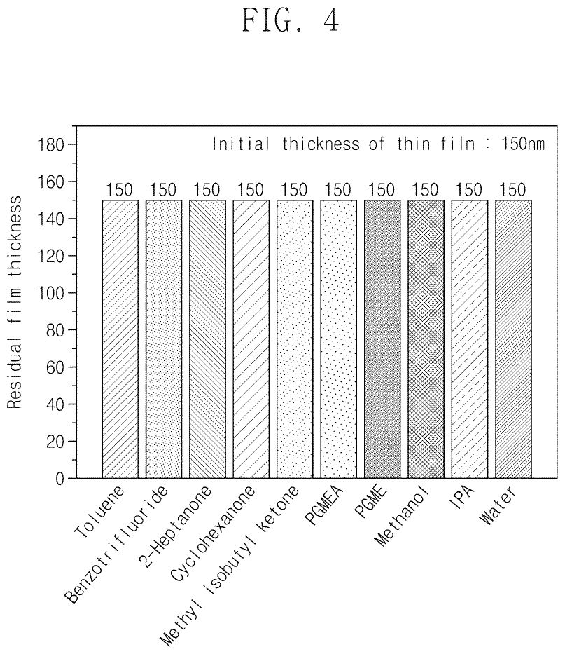

FIG. 3 and FIG. 4 are graphs showing the evaluation results of the solubility of the underlayer compounds according to embodiments of the inventive concept.

Referring to FIG. 3, it could be confirmed that the underlayer thin film (the underlayer compound of Formula 1) formed on the substrate according to Experimental Example 1 could be dissolved in a polar organic solvent (for example, PGME, PGMEA, 2-heptanone, MIBK, methanol and water) but could not be dissolved in a hydrophobic or aromatic solvent (for example, toluene, and benzotrifluoride). The underlayer compound of Formula 1 may have hydrophilicity, and accordingly, the underlayer compound of Formula 1 may be insoluble in a hydrophobic or aromatic solvent.

Referring to FIG. 4, it could be confirmed that the underlayer thin film (the underlayer compound of Formula 5) formed on the substrate according to Experimental Example 2 was not dissolved in a polar organic solvent (for example, 2-heptanone, MIBK, PGMEA, PGME, methanol, cyclohexanone, IPA and water) as well as a hydrophobic or aromatic solvent (for example, toluene and benzotrifluoride). That is, the underlayer compound of Formula 5 may have insolubility in a hydrophobic or aromatic solvent, and a polar organic solvent.

A Resist Compound According to Embodiments of the Inventive Concept Will be Explained.

The resist compound according to embodiments of the inventive concept may be used for the manufacture of a semiconductor device, and a photolithography process for manufacturing the semiconductor device may be used. The resist compound may be used, for example, in an extreme ultraviolet or e-beam lithography process. The extreme ultraviolet may mean ultraviolet having a wavelength of about 10 nm to about 124 nm, in detail, a wavelength of about 13.0 nm to about 13.9 nm, in more detail, a wavelength of about 13.4 nm to about 13.6 nm.

The resist compound may include an alkylated metal oxide nanocluster having a counter anion. The alkylated metal oxide nanocluster may include a core structure including a metal oxide, and an alkyl group of 1 to 20 carbon atoms, combined with the metal element of the core structure. The core structure may include a cation which may form an ionic bond with the counter anion. The counter anion may be an alkyl carboxylic acid anion of 2 to 20 carbon atoms, an alkyl ether alkyl carboxylic acid anion of 3 to 20 carbon atoms, an alkyl ether alkyl ether alkyl carboxylic acid anion of 4 to 20 carbon atoms, a fluoroalkyl carboxylic acid anion of 2 to 20 carbon atoms, a fluoroalkyl ether fluoroalkyl carboxylic acid anion of 3 to 20 carbon atoms, or a fluoroalkyl ether fluoroalkyl ether fluoroalkyl carboxylic acid anion of 4 to 20 carbon atoms.

The resist compound may include a structure of Formula 12.

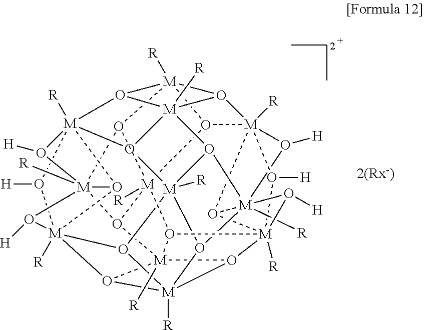

In Formula 12, M may be at least one selected from the group consisting of tin (Sn), zinc (Zn), lithium (Li), sodium (Na), potassium (K), beryllium (Be), magnesium (Mg), calcium (Ca), barium (Ba), aluminum (Al), silicon (Si), cadmium (Cd), mercury (Hg), chromium (Cr), iron (Fe), cobalt (Co), nickel (Ni), copper (Cu), germanium (Ge), palladium (Pd), platinum (Pt), lead (Pb), strontium (Sr), and manganese (Mn), and R is an alkyl group of 1 to 20 carbon atoms. Rx⁻ is the counter anion and is the alkyl carboxylic acid anion of 2 to 20 carbon atoms, the alkyl ether alkyl carboxylic acid anion of 3 to 20 carbon atoms, the alkyl ether alkyl ether alkyl carboxylic acid anion of 4 to 20 carbon atoms, the fluoroalkyl carboxylic acid anion of 2 to 20 carbon atoms, the fluoroalkyl ether fluoroalkyl carboxylic acid anion of 3 to 20 carbon atoms, or the fluoroalkyl ether fluoroalkyl ether fluoroalkyl carboxylic acid anion of 4 to 20 carbon atoms. In the description, fluoroalkyl is an alkyl group of which at least one hydrogen is substituted with fluorine.

The resist compound may include an alkylated tin oxide nanocluster having the counter anion. The alkylated tin oxide nanocluster may include a core structure including tin oxide, and an alkyl group of 1 to 20 carbon atoms, combined with the tin element of the core structure. The core structure may include a cation and may make an ionic bond with the counter cation.

The resist compound may include, for example, a structure of Formula 12-1.

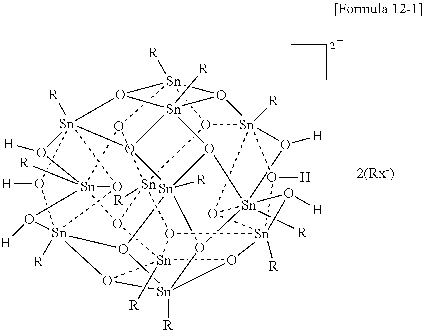

In Formula 12-1, R is —CH₂CH₂CH₂CH₃, and Rx⁻ is the counter anion and is the fluoroalkyl carboxylic acid anion of 2 to 20 carbon atoms, the fluoroalkyl ether fluoroalkyl carboxylic acid anion of 3 to 20 carbon atoms, or the fluoroalkyl ether fluoroalkyl ether fluoroalkyl carboxylic acid anion of 4 to 20 carbon atoms. Rx⁻ may have a structure of, for example, CF₃(CF₂)ₐCOO⁻, CF₃(CF₂)_{b}CFCF₃COO⁻·CF₃(CF₂)₂—O—CFCF₃COO⁻ or CF₃(CF₂)₂—O—CFCF₃CF₂—O—CFCF₃COO⁻ (where, “a” is an integer of 1 to 18, and “b” is an integer of 1 to 16). Rx⁻ may have a structure of, for example, CF₃(CF₂)₂—O—CFCF₃COO⁻.

The synthesis of the resist compound of Formula 12-1 may be carried out according to Reaction 2.

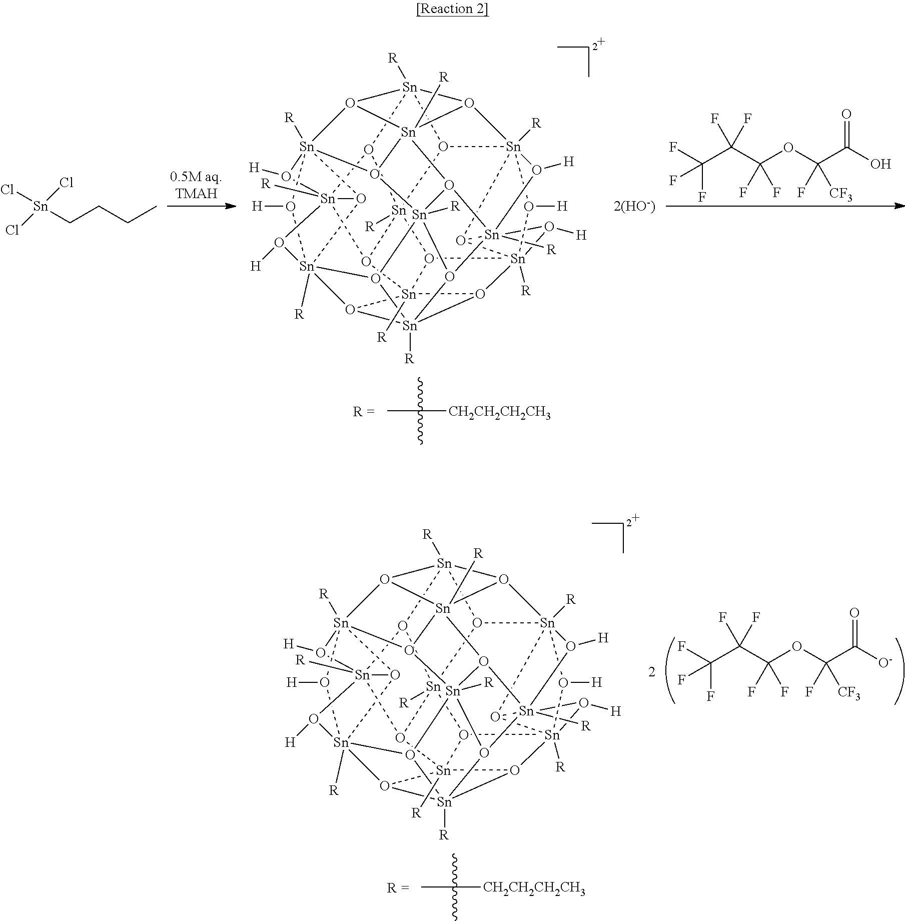

### [Synthetic Example 3] Synthesis of Resist Compound of Formula 12-1 (Reaction 2)

In a 100 cm³ vial, tetramethylammonium hydroxide pentahydrate (5.78 g, 31.9 mmol) was dissolved in deionized water (DI water, 64 cm³), and butyltin trichloride (3.0 g, 10.6 mmol) was rapidly injected to form a first reaction solution. The first reaction solution was vigorously stirred at room temperature for about 1 hour, and the product thus obtained was filtered, while washing with DI water several times. The product was dried in vacuum to obtain an alkylated tin oxide cluster of a white solid phase (BTOC, 1.8 g). After that, the BTOC (0.4 g, 0.16 mmol) thus synthesized was dissolved in tetrahydrofuran (THF, 2 cm³), and perfluoro(2-methyl-3-oxahexanoic)acid (0.11 g, 0.32 mmol) was added thereto to produce a second reaction solution. The second reaction solution was stirred at about 50° C. for about 30 minutes to concentrate. The concentrated material was dissolved in benzotrifluoride (1.6 cm³), and the resultant was injected to HFE-7500 (purchased from 3M Co.) to form a precipitate, and the precipitate was filtered and recovered. The recovered material was dried in vacuum to obtain the resist compound (H-BTOC) of Formula 12-1 as a final product with a white solid phase (0.3 g).

The resist compound may have hydrophobicity and may have solubility in a hydrophobic or aromatic solvent. The resist compound may include secondary electrons produced by light irradiation, and radicals produced by the secondary electrons. In an embodiment, if the counter anion (Rx) of the resist compound is the fluoroalkyl carboxylic acid anion, the C—F bond of a fluoroalkyl chain may be cleaved by the secondary electrons produced by the irradiation of light (for example, extreme ultraviolet) during an exposing process, and accordingly, carbon radicals may be produced in the resist compound. The radical (for example, carbon radical) in the resist compound may make a chemical bond with a vinyl silyl group in the underlayer compound. In an embodiment, while the double bond between carbon atoms in the vinyl silyl group in the underlayer compound is cleaved, the vinyl silyl group in the underlayer compound may be combined with the radical (for example, the carbon radical) in the underlayer compound.

A Method for Manufacturing Semiconductor Device Using Underlayer Compound and Resist Compound According to Embodiments of the Inventive Concept

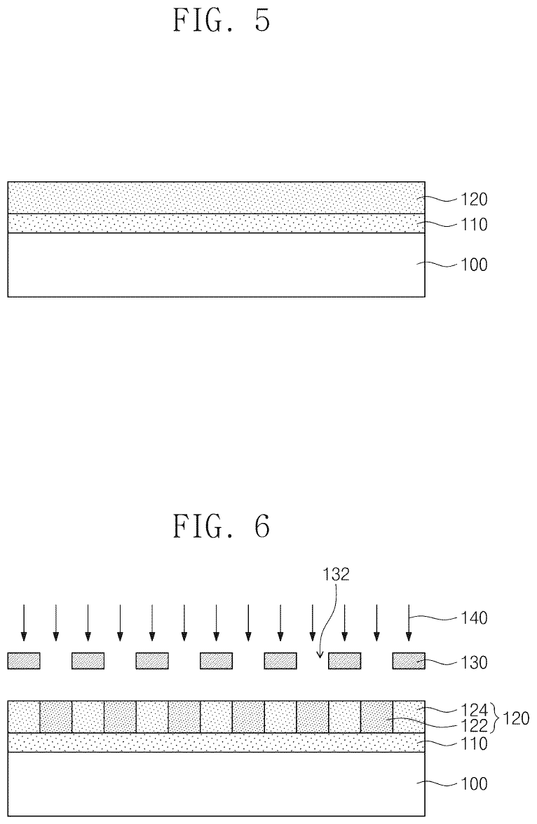

FIG. 5 to FIG. 8 are cross-sectional views showing a method for manufacturing a semiconductor device according to embodiments of the inventive concept.

Referring to FIG. 5, an underlayer 110 may be formed on a lower layer 100, and on the underlayer 110, a photoresist layer 120 may be formed. The lower layer 100 may be an etching target layer, and may be formed by any one selected among a semiconductor material, a conductive material, an insulating material, or combinations thereof. The lower layer 100 may be formed as a single layer or may include stacked multiple layers.

The underlayer 110 may include the underlayer compound having hydrophilicity. The underlayer compound may include the structure of Formula 1 or Formula 5. The formation of the underlayer 110 may include applying the underlayer compound on the lower layer 100. In an embodiment, the application of the underlayer compound may be performed by a spin coating method.

The photoresist layer 120 may include the resist compound having hydrophobicity. The resist compound may include the structure of Formula 12. The formation of the photoresist layer 120 may include applying the resist compound on the underlayer 110. In an embodiment, the applying of the resist compound may include spin coating of the resist compound on the underlayer 110 by using a hydrophobic or aromatic solvent. The formation of the photoresist layer 120 may further include performing heating process (for example, a soft baking process) on the resist compound applied.

According to embodiments of the inventive concept, the photoresist layer 120 may be formed by applying the resist compound using a hydrophobic or aromatic solvent on the underlayer 110. The underlayer compound of Formula 1 may not have solubility in a hydrophobic or aromatic solvent, and the underlayer compound of Formula 5 may not have solubility in a polar organic solvent as well as a hydrophobic or aromatic solvent. Accordingly, the damage of the underlayer 110 may be prevented during forming the photoresist layer 120 using a hydrophobic or aromatic solvent.

Referring to FIG. 6, an exposing process may be performed on the photoresist layer 120. The exposing process may include arranging a photomask 130 on the photoresist layer 120, and irradiating light 140 on the photoresist layer 120 through the photomask 130. The light 140 may be e-beam or extreme ultraviolet. The photoresist layer 120 may include a first part 122 exposed to the light 140 and a second part 124 unexposed to the light 140. The light 140 may be irradiated to the first part 122 through an opening 132 of the photomask 130, and may not be irradiated to the second part 124 due to the block by the photomask 130.

The resist compound may further include radicals produced by the irradiation of the light 140. In an embodiment, if the counter anion (Rx) of the resist compound of Formula 12 is a fluoroalkyl carboxylic acid anion, the C—F bond of a fluoroalkyl chain may be cleaved by secondary electrons produced by the irradiation of the light 140 to produce carbon radicals. In the first part 122 of the photoresist layer 120, the resist compound may include the radicals (for example, the carbon radicals) produced by the irradiation of the light 140, and materials represented by Formula 12 may be combined with each other through the radicals (for example, the carbon radicals). Accordingly, in the first part 122 of the photoresist layer 120, the resist compound may include a crosslinked structure of the materials represented by Formula 12. In the second part 124 of the photoresist layer 120, the chemical structure of the resist compound may not be changed. As a result, after the exposing process, there may be a solubility difference between the first part 122 and the second part 124.

The radical (for example, the carbon radical) produced in the resist compound by the irradiation of the light 140 may make a chemical bond with a vinyl silyl group in the underlayer compound. In an embodiment, while the double bond between carbon atoms of the vinyl silyl group in the underlayer compound is cleaved, the vinyl silyl group in the underlayer compound may be combined with the radical (for example, the carbon radical) in the resist compound. As a result, the first part 122 of the photoresist layer 120 may be fixed on the underlayer 110 via the chemical bond with the underlayer 110, and accordingly, the adhesiveness between the exposed photoresist layer 120 and the underlayer 110 may increase. In this case, an additional heating process (for example, a baking process) for fixing the photoresist layer 120 onto the underlayer 110 may be omitted.

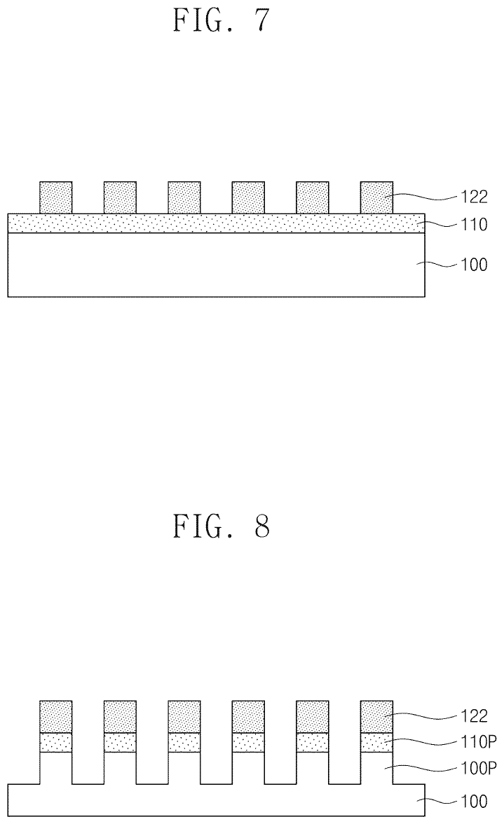

Referring to FIG. 7, after the exposing process, the photomask 130 may be removed. A developing process may be performed on the exposed photoresist layer 120. The developing process may include removing the second part 124 of the photoresist layer 120 by using a hydrophobic or aromatic solvent. The first part 122 of the photoresist layer 120 may be referred to as a photoresist pattern. By the developing process, the second part 124 of the photoresist layer 120 may be selectively removed, and the photoresist pattern 122 may be a negative tone pattern.

According to embodiments of the inventive concept, the developing process may be performed using a hydrophobic or aromatic developing solution. The underlayer compound of Formula 1 may not have solubility in a hydrophobic or aromatic solvent, and the underlayer compound of Formula 5 may not have solubility in a polar organic solvent as well as a hydrophobic or aromatic solvent. Accordingly, during the developing process using a hydrophobic or aromatic developing solution, the damage of the underlayer 110 may be prevented.

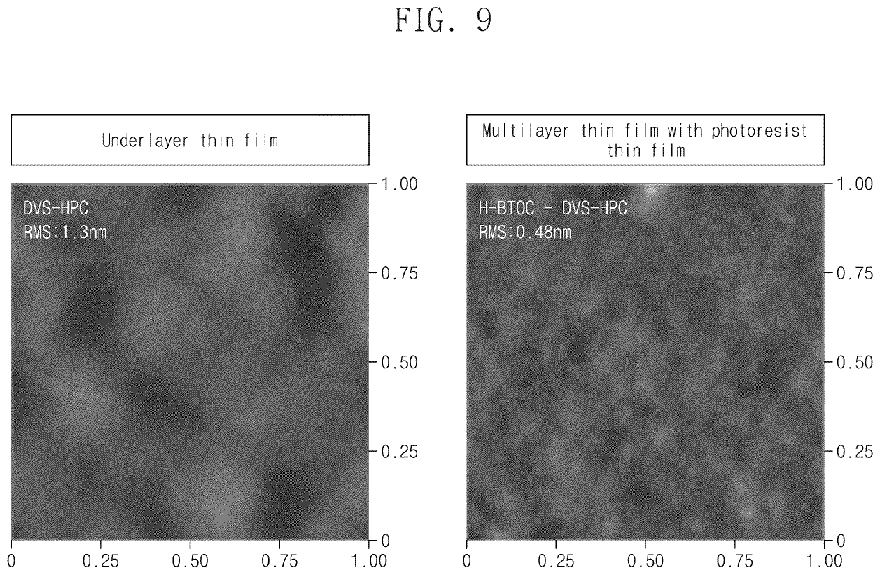

Referring to FIG. 8, the underlayer 110 and the lower layer 100 may be etched using the photoresist pattern 122 as an etching mask. The etching of the underlayer 110 and the lower layer 100 may include, for example, a wet or dry etching process. The underlayer 110 may be etched to form an underlayer pattern 110P, and the upper portion of the lower layer 100 may be etched to form a lower pattern 100P. After forming the lower pattern 100P, the photoresist pattern 122 and the underlayer pattern 110P may be removed. The lower pattern 100P may be a semiconductor pattern, a conductive pattern, or an insulating pattern in a semiconductor device.

According to the inventive concept, the underlayer compound may have hydrophilicity and may not have solubility in a hydrophobic or aromatic solvent. The resist compound may have hydrophobicity and may have solubility in a hydrophobic or aromatic solvent. The photoresist layer 120 may be formed by applying the resist compound using a hydrophobic or aromatic solvent on the underlayer 110, and the developing process of the photoresist layer 120 may be performed using a hydrophobic or aromatic developing solution. Since the underlayer compound does not have solubility in a hydrophobic or aromatic solvent, the damage of the underlayer 110 may be prevented during the forming of the photoresist layer 120 and the developing process.

Further, the underlayer compound may include a vinyl silyl group, and the vinyl silyl group of the underlayer compound may be chemically bonded to the radical (for example, the carbon radical) produced in the resist compound. Accordingly, the first part 122 (that is, the photoresist pattern) of the photoresist layer 120 may be fixed onto the underlayer 110 via the chemical bond with the underlayer 110. As a result, the adhesiveness between the photoresist pattern 122 and the underlayer 110 may increase, and the collapse of the photoresist pattern 122 may be restrained. Further, since the adhesiveness between the photoresist pattern 122 and the underlayer 110 increases, a dosage required for the exposing process for forming the photoresist pattern 122 may be reduced. Accordingly, the resolution and sensitivity of the photoresist pattern 122 may be improved.

A Multilayer Structure Formed Using the Underlayer Compound and the Resist Compound According to Embodiments of the Inventive Concept Will be Explained.

According to some embodiments, a multilayer structure may include the lower layer 100, the underlayer 110 and the photoresist layer 120, as explained referring to FIG. 5. The underlayer 110 may include the underlayer compound having hydrophilicity, and the underlayer compound may include the structure of Formula 1 or Formula 5. The photoresist layer 120 may include the resist compound having hydrophobicity, and the resist compound may include the structure of Formula 12.

According to some embodiments, the multilayer structure may include the lower layer 100, the underlayer 110 and the photoresist layer 120, as explained referring to FIG. 6. The photoresist layer 120 may include the first part 122 exposed to the light 140, and the second part 124 unexposed to the light 140. In the first part 122 of the photoresist layer 120, the resist compound may include the radicals produced by the irradiation of the light 140. In an embodiment, in case where the counter anion (Rx) of the resist compound of Formula 12 is a fluoroalkyl carboxylic acid anion, the first part 122 of the photoresist layer 120 may include carbon radicals produced by the irradiation of the light 140. In the first part 122 of the photoresist layer 120, materials represented by Formula 12 may be combined with each other via the radicals (for example, the carbon radicals). Accordingly, in the first part 122 of the photoresist layer 120, the resist compound may include a crosslinked structure of the materials represented by Formula 12. In the first part 122 of the photoresist layer 120, the radical (for example, the carbon radical) may make a chemical bond with a vinyl silyl group in the underlayer compound. Accordingly, the first part 122 of the photoresist layer 120 may be fixed onto the underlayer 110 via the chemical bond with the underlayer 110.

According to some embodiments, the multilayer structure may include the lower layer 100, the underlayer 110 and the photoresist pattern 122 as explained referring to FIG. 7. The photoresist pattern 122 may be the same as the first part 122 of the photoresist layer 120.

### [Experimental Example 3] Formation of Underlayer and Photoresist Layer

A solution (about 0.5 wt/vol %) of the underlayer compound (DVS-HPC) of Formula 1 synthesized in Synthetic Example 1 dissolved in propylene glycol mono-methyl ether (PGME) was applied by spin coating on a surface-untreated silicon substrate (bare Si substrate) at about 3000 rpm for about 60 seconds, and heated at about 80° C. for about 1 minute to form an underlayer thin film (a thickness of about 25 nm). After that, a H-BTOC solution (about 2 wt/vol %) of the resist compound (H-BTOC) of Formula 12-1 synthesized in Synthetic Example 13 dissolved in benzotrifluoride was applied by spin coating on the underlayer thin film at about 3000 rpm for about 60 seconds, and heated at about 80° C. for about 1 minute to form a photoresist thin film (a thickness of about 75 nm). After stacking the underlayer thin film and the photoresist thin film, the thickness of the multilayer thin film was confirmed as about 100 nm.

FIG. 9 shows atomic force microscopic images showing measurement results on the surface roughness of an underlayer and a photoresist thin film, formed according to Experimental Example 3.

Referring to FIG. 9, the surface roughness of the underlayer thin film formed according to Experimental Example 3 was measured using an atomic force microscope, and the formation of a uniform thin film with a RMS roughness value of about 1.3 nm was confirmed. After that, the surface roughness of the photoresist thin film formed on the underlayer thin film according to Experimental Example 3 was measured using an atomic force microscope, and the formation of a uniform thin film with a RMS roughness value of about 0.48 nm was confirmed.

### [Experimental Example 4] Evaluation of Change of Solubility of Photoresist Thin Film According to e-Beam Dosage

### 1) Formation of Photoresist Pattern on Substrate without Underlayer (Comparative Example)

A solution (about 1.8 wt/vol %) of the resist compound (H-BTOC) of Formula 12-1 synthesized in Synthetic Example 3 dissolved in benzotrifluoride was applied by spin coating on a surface-untreated silicon substrate at about 1500 rpm for about 60 seconds, and heated at about 80° C. for about 1 minute to form a photoresist thin film (a thickness of about 80 nm). On the photoresist thin film, e-beam of about 50 μC/cm² to about 1,500 μC/cm² was irradiated under an accelerated voltage of about 80 keV. A developing process was performed using benzotrifluoride for about 60 seconds to form a negative tone photoresist pattern. After that, the thickness of the remaining photoresist pattern was measured using Alpha-Step® D-300 stylus profiler manufactured by Kla-Tencor Co., and the solubility change properties were evaluated.

### 2) Formation of Photoresist Pattern on Substrate Coated with Underlayer (Experimental Example)

On the multilayer thin film formed in Experimental Example 3, e-beam of about 50 μC/cm² to about 1,500 μC/cm² was irradiated under an accelerated voltage of about 80 keV. A developing process was performed using benzotrifluoride for about 60 seconds to form a negative tone photoresist pattern. After that, the thickness of the remaining photoresist pattern was measured using Alpha-Step® D-300 stylus profiler manufactured by Kla-Tencor Co., and the solubility change properties were evaluated.

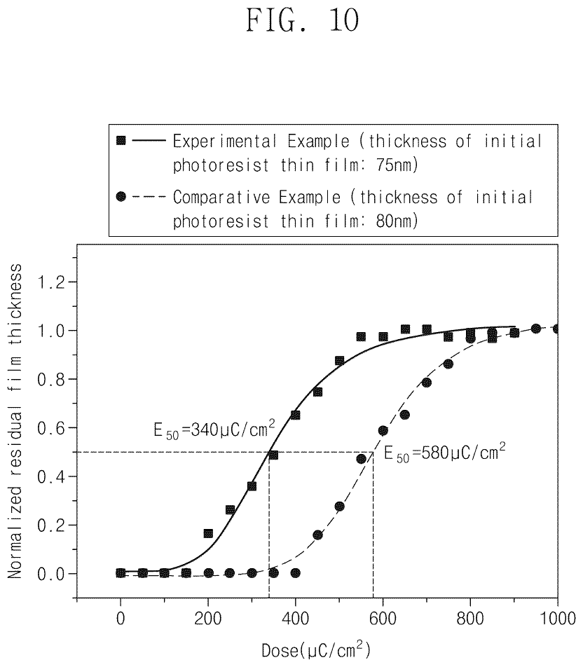

FIG. 10 is a graph showing the evaluation results on the solubility change of a photoresist thin film according to Experimental Example 4.

Referring to FIG. 10, in the case of the surface-untreated silicon substrate (bare) (Comparative Example), when the e-beam of about 580 μC/cm² was irradiated onto the photoresist thin film, the thickness of the photoresist pattern could be maintained to about 50% of the thickness of the photoresist thin film. In the case of the substrate coated with the underlayer (Experimental Example), when the e-beam of about 340 μC/cm² was irradiated onto the photoresist thin film, the thickness of the photoresist pattern could be maintained to about 50% of the thickness of the photoresist thin film. That is, it could be confirmed that the negative tone photoresist pattern could be formed on the substrate coated with the underlayer by using a relatively less e-beam dosage.

### [Experimental Example 5] Formation of Photoresist Pattern According to Irradiation of e-Beam

### 1) Formation of Photoresist Pattern on Substrate without Underlayer (Comparative Example)

A H-BTOC solution (about 1.8 wt/vol %) of the resist compound (H-BTOC) of Formula 12-1 synthesized in Synthetic Example 3 dissolved in benzotrifluoride was applied by spin coating on a surface-untreated silicon substrate at about 1500 rpm for about 60 seconds, and heated at about 80° C. for about 1 minute to form a photoresist thin film (a thickness of about 80 nm). On the photoresist thin film, e-beam of about 50 μC/cm² to about 1,500 μC/cm² was irradiated under an accelerated voltage of about 80 keV. A developing process was performed using benzotrifluoride for about 30 seconds to form a negative tone photoresist pattern having a line width of about 50 nm to about 100 nm.

### 2) Formation of Photoresist Pattern on Substrate Coated with Underlayer (Experimental Example)

On the multilayer thin film formed in Experimental Example 3, e-beam of about 50 μC/cm² to about 1,500 μC/cm² was irradiated under an accelerated voltage of about 80 keV. A developing process was performed using benzotrifluoride for about 30 seconds to form a negative tone photoresist pattern having a line width of about 50 nm to about 100 nm.

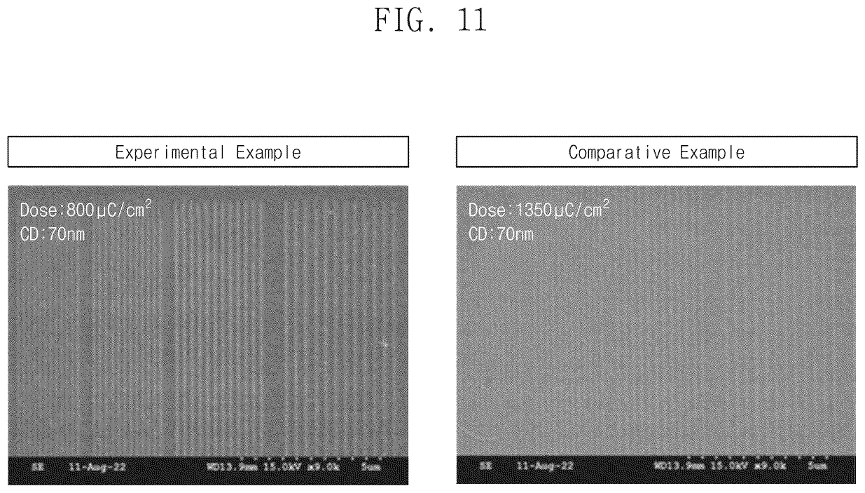

FIG. 11 shows scanning electron microscopic images of a photoresist pattern formed according to Experimental Example 5.

Referring to FIG. 11, in the case of the surface-untreated silicon substrate (bare) (Comparative Example), when the e-beam of about 1350 μC/cm² was irradiated, a negative tone photoresist pattern having a line width of about 70 nm was formed. In the case of the substrate coated with underlayer (Experimental Example), when the e-beam of about 800 μC/cm² was irradiated, a negative tone photoresist pattern having a line width of about 70 nm was formed. That is, in the case of the substrate coated with underlayer, it could be confirmed that the negative tone photoresist pattern could be formed by using a relatively less e-beam dosage.

### [Experimental Example 6] Evaluation of Solubility Change of Photoresist Thin Film According to Dosage of Extreme Ultraviolet

### 1) Formation of Photoresist Pattern on Substrate Coated with DVS

A solution (about 20 wt) of 1-3-divinyltetramethyldisilazane (DVS) dissolved in propylene glycol monomethyl ether acetate (PGMEA) was applied by spin coating on a surface-untreated silicon substrate (bare Si substrate) at about 3000 rpm for about 30 seconds, and heated at about 110° C. for about 1 minute for coating DVS on the silicon substrate. After that, on the DVS-coated silicon substrate, a H-BTOC solution (about 0.9 wt/vol %) of the resist compound (H-BTOC) of Formula 12-1 synthesized in Synthetic Example 3 dissolved in benzotrifluoride was applied by spin coating at about 3000 rpm for about 60 seconds, and heated at about 80° C. for about 1 minute to form a photoresist thin film (a thickness of about 23 nm). After that, on the photoresist thin film, extreme ultraviolet (EUV) was irradiated (a dosage of about 2 mJ/cm² to about 80 mJ/cm²) using a METS stepper belonged to Lawrence Berkeley National Laboratory in America, and a developing process was performed using benzotrifluoride for about 20 seconds to form a negative tone photoresist pattern. After that, the thickness of the remaining photoresist pattern was measured using Alpha-Step® D-300 stylus profiler manufactured by Kla-Tencor Co., and the solubility change properties of the photoresist thin film were evaluated.

### 2) Formation of Photoresist Pattern on Substrate Coated with Underlayer (DVS-HPC) (Experimental Example)

A solution (about 0.5 wt/vol %) of the underlayer compound (DVS-HPC) of Formula 1 synthesized in Synthetic Example 1 dissolved in propylene glycol mono-methyl ether (PGME) was applied by spin coating on a surface-untreated silicon substrate (bare Si substrate) at about 3000 rpm for about 60 seconds, and heated at about 80° C. for about 1 minute to form an underlayer thin film (a thickness of about 23 nm). After that, a H-BTOC solution (about 0.9 wt/vol %) of the resist compound (H-BTOC) of Formula 12-1 synthesized in Synthetic Example 3 dissolved in benzotrifluoride was applied on the underlayer thin film by spin coating at about 3000 rpm for about 60 seconds, and heated at about 80° C. for about 1 minute to form a photoresist thin film (a thickness of about 23 nm). After that, on the photoresist thin film, extreme ultraviolet (EUV) was irradiated (a dosage of about 1 mJ/cm² to 40 mJ/cm²) using a METS stepper belonged to Lawrence Berkeley National Laboratory, and a developing process was performed using benzotrifluoride for about 20 seconds to form a negative tone photoresist pattern. After that, the thickness of the remaining photoresist pattern was measured using Alpha-Step® D-300 stylus profiler manufactured by Kla-Tencor Co., and the solubility change properties of the photoresist thin film were evaluated.

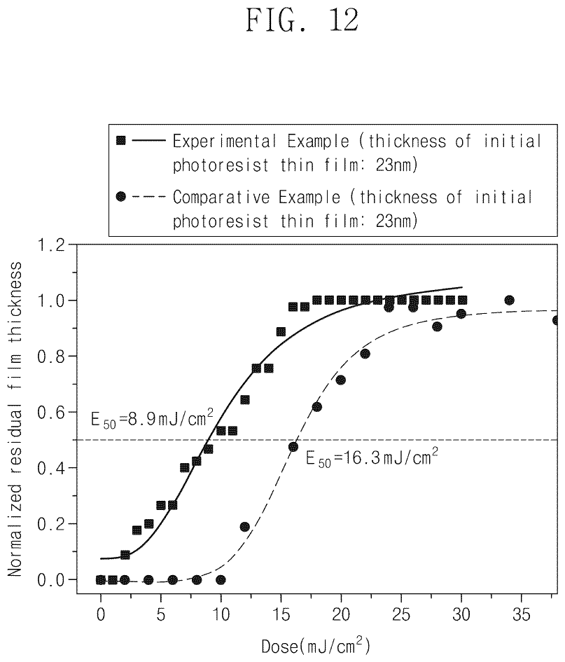

FIG. 12 is a graph showing the evaluation results on the solubility change of a photoresist thin film according to Experimental Example 6.

Referring to FIG. 12, in the case of the silicon substrate coated with DVS (Comparative Example), when the extreme ultraviolet of about 16.3 mJ/cm² was irradiated onto the photoresist thin film, the thickness of the photoresist pattern could be maintained to about 50% of the photoresist thin film. In the case of the substrate coated with the underlayer (DVS-HPC) (Experimental Example), when the extreme ultraviolet of about 8.9 mJ/cm² was irradiated onto the photoresist thin film, the thickness of the photoresist pattern could be maintained to about 50% of the photoresist thin film. That is, in the case of the substrate coated with underlayer (DVS-HPC), it could be confirmed that the negative tone photoresist pattern could be formed by using a relatively less extreme ultraviolet dosage.

According to the inventive concept, the underlayer compound may have hydrophilicity and may not have solubility in a hydrophobic or aromatic solvent. The resist compound may have hydrophobicity and may have solubility in a hydrophobic or aromatic solvent. The photoresist layer 120 may be formed by applying the resist compound using a hydrophobic or aromatic solvent on the underlayer 110, and the developing process of the photoresist layer 120 may be performed using a hydrophobic or aromatic developing solution. Because the underlayer compound does not have solubility in a hydrophobic or aromatic solvent, the damage of the underlayer 110 could be prevented during the formation of the photoresist layer 120 and the developing process.

In addition, in case where the underlayer compound includes the structure of Formula 5, the underlayer compound may not have solubility in a polar organic solvent as well as a hydrophobic or aromatic solvent. Accordingly, the degree of freedom of selecting a solvent for coating or a developing solution may increase during the formation of the photoresist layer 120 and the developing process.

Further, the underlayer compound may include a vinyl silyl group, and the vinyl silyl group of the underlayer compound may make a chemical bond with a radical (for example, a carbon radical) produced in the resist compound. Accordingly, the adhesiveness between the photoresist pattern 122 and the underlayer 110 may increase, and the collapse of the photoresist pattern 122 may be restrained. In addition, according to the increase of the adhesiveness between the photoresist pattern 122 and the underlayer 110, a dosage required during the exposing process for forming the photoresist pattern 122 may be reduced. As a result, the solubility and sensitivity of the photoresist pattern 122 may be improved.

Accordingly, a resist compound and an underlayer compound, capable of increasing the resolution and sensitivity of the photoresist pattern and restraining the collapse of the photoresist pattern, a multilayered structure formed using the same, and a method for manufacturing a semiconductor device using the same, may be provided.

According to the inventive concept, the underlayer compound may have hydrophilicity and may not have solubility in a hydrophobic or aromatic solvent.

The resist compound may have hydrophobicity and may have solubility in a hydrophobic or aromatic solvent. Accordingly, the damage of an underlayer during forming a photoresist layer performed using a hydrophobic or aromatic solvent, and during a developing process performed using a hydrophobic or aromatic developing solution may be prevented.

Further, the underlayer compound may include a vinyl silyl group, and the vinyl silyl group of the underlayer compound may make a chemical bond with a radical (for example, a carbon radical) produced in the resist compound. Accordingly, adhesiveness between the photoresist pattern and the underlayer may increase, and the collapse of the photoresist pattern may be restrained. Further, due to the increase of the adhesiveness between the photoresist pattern and the underlayer, a dosage required during an exposing process for forming the photoresist pattern may be reduced, and as a result, the resolution and sensitivity of the photoresist pattern may be improved.

Accordingly, a resist compound and an underlayer compound, capable of increasing the resolution and sensitivity of the photoresist pattern and restraining the collapse of the photoresist pattern, a multilayered structure formed using the same, and a method for manufacturing a semiconductor device using the same, may be provided.

Although the embodiments of the present invention have been described, it is understood that the present invention should not be limited to the embodiments, but various changes and modifications can be made by one ordinary skilled in the art within the spirit and scope of the present invention as hereinafter claimed.

What is claimed is:

1. An underlayer compound for photolithography, comprising a structure of the following Formula 1: 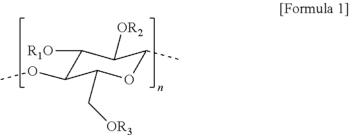
in Formula 1, R₁, R₂ and R₃ are each independently hydrogen, deuterium, or a functional group represented by the following Formula 2, Formula 3 or Formula 4, and “n” is an integer of 2 to 10,000: 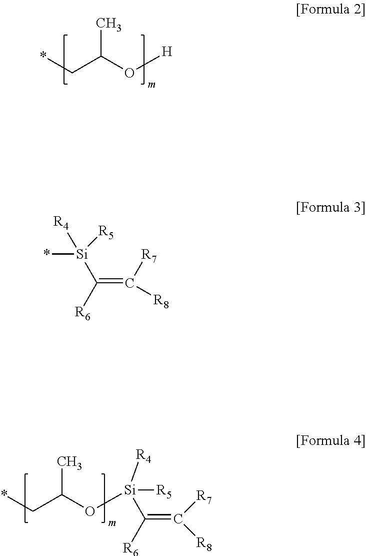
in Formula 2 and Formula 4, “m” is an integer of 1 to 20,
in Formula 3 and Formula 4, R₄, R₅, R₆, R₇ and R₈ are each independently hydrogen, deuterium, or an alkyl group of 1 to 3 carbon atoms, and
in Formula 2 to Formula 4, * is a part combined with oxygen in Formula 1.

2. The underlayer compound for photolithography of claim 1, wherein the underlayer compound has hydrophilicity.

3. The underlayer compound for photolithography of claim 1, wherein, in Formula 1, at least one among R₁, R₂ and R₃ is the functional group represented by Formula 3 or Formula 4.

4. The underlayer compound for photolithography of claim 3, wherein, in Formula 1, another one among R₁, R₂ and R₃ is hydrogen, deuterium or the functional group represented by Formula 2.

5. The underlayer compound for photolithography of claim 1, wherein the underlayer compound comprises a crosslinked structure of materials represented by Formula 1, by using tetramethoxymethyl glycoluril (TMMGU) as a curing agent.

6. A resist compound for photolithography, comprising an alkylated metal oxide nanocluster having a counter anion, wherein
the alkylated metal oxide nanocluster comprises a core structure comprising a metal oxide and an alkyl group of 1 to 20 carbon atoms, bonded to a metal element of the core structure, and
the counter anion is an alkyl carboxylic acid anion of 2 to 20 carbon atoms, an alkyl ether alkyl carboxylic acid anion of 3 to 20 carbon atoms, an alkyl ether alkyl ether alkyl carboxylic acid anion of 4 to 20 carbon atoms, a fluoroalkyl carboxylic acid anion of 2 to 20 carbon atoms, a fluoroalkyl ether fluoroalkyl carboxylic acid anion of 3 to 20 carbon atoms or a fluoroalkyl ether fluoroalkyl ether fluoroalkyl carboxylic acid anion of 4 to 20 carbon atoms.

7. The resist compound for photolithography of claim 6, wherein the resist compound comprises a structure of Formula 12: 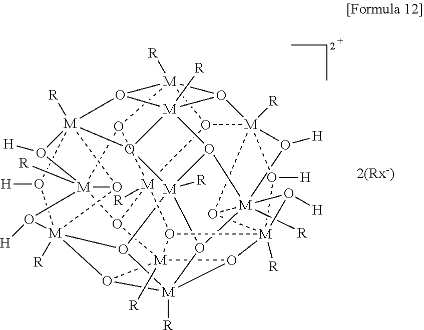
in Formula 12, M is at least one selected from the group consisting of tin (Sn), zinc (Zn), lithium (Li), sodium (Na), potassium (K), beryllium (Be), magnesium (Mg), calcium (Ca), barium (Ba), aluminum (Al), silicon (Si), cadmium (Cd), mercury (Hg), chromium (Cr), iron (Fe), cobalt (Co), nickel (Ni), copper (Cu), germanium (Ge), palladium (Pd), platinum (Pt), lead (Pb), strontium (Sr), and manganese (Mn),
R is an alkyl group of 1 to 20 carbon atoms, and
Rx⁻ is the counter anion and is the alkyl carboxylic acid anion of 2 to 20 carbon atoms, the alkyl ether alkyl carboxylic acid anion of 3 to 20 carbon atoms, the alkyl ether alkyl ether alkyl carboxylic acid anion of 4 to 20 carbon atoms, the fluoroalkyl carboxylic acid anion of 2 to 20 carbon atoms, the fluoroalkyl ether fluoroalkyl carboxylic acid anion of 3 to 20 carbon atoms or the fluoroalkyl ether fluoroalkyl ether fluoroalkyl carboxylic acid anion of 4 to 20 carbon atoms.

8. The resist compound for photolithography of claim 7, wherein, in Formula 12, M is tin (Sn), and R is —CH₂CH₂CH₂CH₃.

9. The resist compound for photolithography of claim 8, wherein Rx has a structure of CF₃(CF₂)ₐCOO⁻, CF₃(CF₂)_{b}CFCF₃COO⁻·CF₃(CF₂)₂—O—CFCF₃COO⁻ or CF₃(CF₂)₂—O—CFCF₃CF₂—O—CFCF₃COO⁻,
“a” is an integer of 1 to 18, and “b” is an integer of 1 to 16.

10. The resist compound for photolithography of claim 7, wherein the resist compound has hydrophobicity.

11. A multilayered structure comprising:
a lower layer;
an underlayer on the lower layer; and
a photoresist layer on the underlayer, wherein
the underlayer comprises a cellulose structure having at least one hydroxyl group (—OH) and at least one vinyl silyl group, and
the photoresist layer comprises an alkylated metal oxide nanocluster having a counter anion, where the alkylated metal oxide nanocluster comprises a core structure comprising a metal oxide and an alkyl group of 1 to 20 carbon atoms, bonded to a metal element of the core structure.

12. The multilayered structure of claim 11, wherein the underlayer comprises an underlayer compound comprising a structure of the following Formula 1: 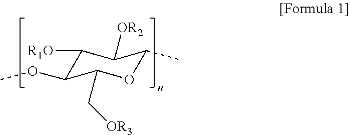
in Formula 1, R₁, R₂ and R₃ are each independently hydrogen, deuterium, or a functional group represented by the following Formula 2, Formula 3 or Formula 4, and “n” is an integer of 2 to 10,000: 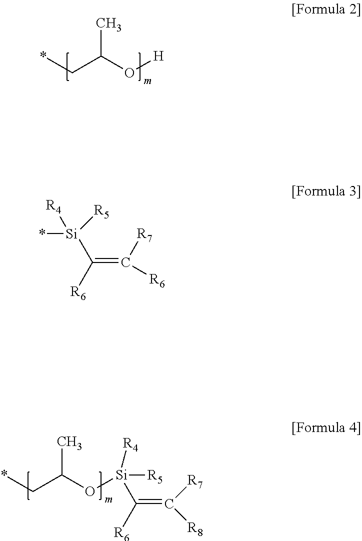
in Formula 2 and Formula 4, “m” is an integer of 1 to 20,
in Formula 3 and Formula 4, R₄, R₅, R₆, R₇ and R₈ are each independently hydrogen, deuterium, or an alkyl group of 1 to 3 carbon atoms, and
in Formula 2 to Formula 4, * is a part combined with oxygen in Formula 1.

13. The multilayer structure of claim 12, wherein, in Formula 1, at least one among R₁, R₂ and R₃ is the functional group represented by Formula 3 or Formula 4.

14. The multilayer structure of claim 13, wherein, in Formula 1, another one among R₁, R₂ and R₃ is hydrogen, deuterium or the functional group represented by Formula 2.

15. The multilayer structure of claim 12, wherein the underlayer compound comprises a crosslinked structure of materials represented by Formula 1, by using tetramethoxymethyl glycoluril (TMMGU) as a curing agent.

16. The multilayer structure of claim 11, wherein the photoresist layer comprises a structure of Formula 12: 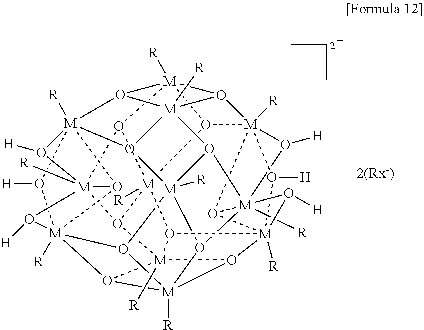
in Formula 12, M is at least one selected from the group consisting of tin (Sn), zinc (Zn), lithium (Li), sodium (Na), potassium (K), beryllium (Be), magnesium (Mg), calcium (Ca), barium (Ba), aluminum (Al), silicon (Si), cadmium (Cd), mercury (Hg), chromium (Cr), iron (Fe), cobalt (Co), nickel (Ni), copper (Cu), germanium (Ge), palladium (Pd), platinum (Pt), lead (Pb), strontium (Sr), and manganese (Mn),
R is an alkyl group of 1 to 20 carbon atoms, and
Rx⁻ is the counter anion and is the alkyl carboxylic acid anion of 2 to 20 carbon atoms, the alkyl ether alkyl carboxylic acid anion of 3 to 20 carbon atoms, the alkyl ether alkyl ether alkyl carboxylic acid anion of 4 to 20 carbon atoms, the fluoroalkyl carboxylic acid anion of 2 to 20 carbon atoms, the fluoroalkyl ether fluoroalkyl carboxylic acid anion of 3 to 20 carbon atoms or the fluoroalkyl ether fluoroalkyl ether fluoroalkyl carboxylic acid anion of 4 to 20 carbon atoms.

17. The multilayer structure of claim 16, wherein the resist compound further comprises carbon radicals, and
the carbon radical of the resist compound makes a chemical bond with a vinyl silyl group of the underlayer.

18. A method for manufacturing a semiconductor device, the method comprising:
forming an underlayer on a lower layer; and
forming a photoresist layer on the under layer, wherein
the forming of the photoresist layer comprises applying a resist compound using a hydrophobic or aromatic solvent on the underlayer,
the underlayer comprises an underlayer compound having hydrophilicity, and
the underlayer compound comprises a cellulose structure having at least one hydroxyl group (—OH) and at least one vinyl silyl group.

19. The method for manufacturing a semiconductor device of claim 18, wherein the underlayer compound comprises a structure of the following Formula 1: 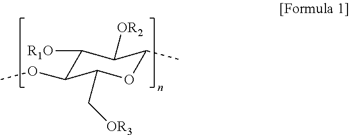
in Formula 1, R₁, R₂ and R₃ are each independently hydrogen, deuterium, or a functional group represented by the following Formula 2, Formula 3 or Formula 4, and “n” is an integer of 2 to 10,000: 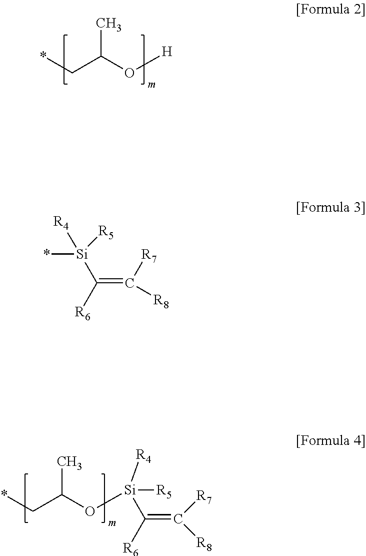
in Formula 2 and Formula 4, “m” is an integer of 1 to 20,
in Formula 3 and Formula 4, R₄, R₅, R₆, R₇ and R₈ are each independently hydrogen, deuterium, or an alkyl group of 1 to 3 carbon atoms, and
in Formula 2 to Formula 4, * is a part combined with oxygen in Formula 1.

20. The method for manufacturing a semiconductor device of claim 19, wherein the underlayer compound comprises a crosslinked structure of materials represented by Formula 1, by using tetramethoxymethyl glycoluril (TMMGU) as a curing agent.

21. The method for manufacturing a semiconductor device of claim 18, wherein the resist compound comprises an alkylated metal oxide nanocluster having a counter anion,
the alkylated metal oxide nanocluster comprises a core structure comprising a metal oxide and an alkyl group of 1 to 20 carbon atoms, bonded to a metal element of the core structure, and
the counter anion is an alkyl carboxylic acid anion of 2 to 20 carbon atoms, an alkyl ether alkyl carboxylic acid anion of 3 to 20 carbon atoms, an alkyl ether alkyl ether alkyl carboxylic acid anion of 4 to 20 carbon atoms, a fluoroalkyl carboxylic acid anion of 2 to 20 carbon atoms, a fluoroalkyl ether fluoroalkyl carboxylic acid anion of 3 to 20 carbon atoms or a fluoroalkyl ether fluoroalkyl ether fluoroalkyl carboxylic acid anion of 4 to 20 carbon atoms.

22. The method for manufacturing a semiconductor device of claim 18, wherein the resist compound comprises a structure of Formula 12: 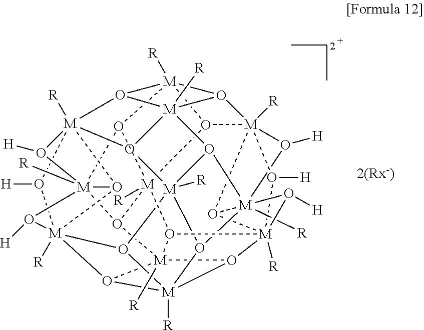
in Formula 12, M is at least one selected from the group consisting of tin (Sn), zinc (Zn), lithium (Li), sodium (Na), potassium (K), beryllium (Be), magnesium (Mg), calcium (Ca), barium (Ba), aluminum (Al), silicon (Si), cadmium (Cd), mercury (Hg), chromium (Cr), iron (Fe), cobalt (Co), nickel (Ni), copper (Cu), germanium (Ge), palladium (Pd), platinum (Pt), lead (Pb), strontium (Sr), and manganese (Mn),
R is an alkyl group of 1 to 20 carbon atoms, and
Rx⁻ is the counter anion and is the alkyl carboxylic acid anion of 2 to 20 carbon atoms, the alkyl ether alkyl carboxylic acid anion of 3 to 20 carbon atoms, the alkyl ether alkyl ether alkyl carboxylic acid anion of 4 to 20 carbon atoms, the fluoroalkyl carboxylic acid anion of 2 to 20 carbon atoms, the fluoroalkyl ether fluoroalkyl carboxylic acid anion of 3 to 20 carbon atoms or the fluoroalkyl ether fluoroalkyl ether fluoroalkyl carboxylic acid anion of 4 to 20 carbon atoms.

23. The method for manufacturing a semiconductor device of claim 18, further comprising performing an exposing process on the photoresist layer, wherein
the exposing process is performed using electron beam (e-beam) or extreme ultraviolet.

24. The method for manufacturing a semiconductor device of claim 23, wherein the photoresist layer comprises a first part exposed by the exposing process, and a second part unexposed by the exposing process,
in the first part of the photoresist layer, the resist compound comprises carbon radicals produced by the e-beam or extreme ultraviolet, and
in the first part of the photoresist layer, the carbon radical of the resist compound makes a chemical bond with the vinyl silyl group of the underlayer compound.

25. The method for manufacturing a semiconductor device of claim 24, further comprising performing a developing process to selectively remove the second part of the photoresist layer, wherein
the developing process is performed using a hydrophobic or aromatic developing solution.
